(19) United States
(12) Patent Application Publication
(10) Pub. No.: US 2025/0370504 A1
(43) Pub. Date: Dec. 4, 2025

(54) DISPLAY DEVICE

(71) Applicant: SAMSUNG DISPLAY CO., LTD., YONGIN-SI (KR)

(72) Inventors: Gwang Taek LEE, Yongin-si (KR); Tae Woo PARK, Yongin-si (KR)

(21) Appl. No.: 19/075,867

(22) Filed: Mar. 11, 2025

(30) Foreign Application Priority Data
May 29, 2024 (KR) 10-2024-0069825

(51) Int. Cl. G06F 1/16; H10K 77/10; H10K 102/00

(52) U.S. Cl. CPC G06F 1/1652; H10K 77/111; H10K 2102/3031; H10K 2102/311

(57) ABSTRACT

A display device includes a display panel including a folding area. A window is disposed on the display panel. The window includes a pattern portion disposed at a position overlapping the folding area. The window includes a first edge extending in a first direction. The pattern portion includes a plurality of groove patterns and a plurality of filling resin patterns disposed in the plurality of groove patterns. The plurality of filling resin patterns are arranged to be spaced apart from each other along the first direction. The plurality of groove patterns extends in a second direction crossing the first direction. Each of the plurality of filling resin patterns has varying heights along the second direction in which mountain portions and valley portions are alternately arranged along the second direction.

### CROSS-REFERENCE TO RELATED APPLICATION

This application claims priority under 35 U.S.C. § 119 to Korean Patent Application No. 10-2024-0069825, filed on May 29, 2024 in the Korean Intellectual Property Office, the disclosure of which is incorporated by reference in its entirety herein.

### 1. TECHNICAL FIELD

The present disclosure relates to a display device.

### 2. DISCUSSION OF RELATED ART

The demand for display devices for displaying images has increased and diversified along with the advancement of the information society. For example, display devices have been applied to various electronic devices such as smartphones, digital cameras, laptop computers, navigation devices, and smart televisions.

To increase portability of the display devices and provide relatively wide display screens, bendable display devices in which a display area may be bent or foldable display devices in which a display area may be folded have been developed.

In the foldable display device, there is a trend to use patterned glass to secure shock resistance and flexibility, which are main characteristics of the foldable display device. Non-penetration type zigzag patterns are formed on the patterned glass used in the foldable display device. In such a foldable display device, a moiré phenomenon may occur due to pixels of a panel and the patterns of the patterned glass. Research is being actively conducted to reduce or prevent the moiré phenomenon.

### SUMMARY

Aspects of the present disclosure provide a display device capable of preventing deterioration of screen quality by reducing a moiré phenomenon.

However, aspects of embodiments of the present disclosure are not restricted to those set forth herein. The above and other aspects of embodiments of the present disclosure will become more apparent to one of ordinary skill in the art to which the present disclosure pertains by referencing the detailed description of the present disclosure given below.

According to an embodiment of the present disclosure, a display device includes a display panel including a folding area. A window is disposed on the display panel. The window includes a pattern portion disposed at a position overlapping the folding area. The window includes a first edge extending in a first direction. The pattern portion includes a plurality of groove patterns and a plurality of filling resin patterns disposed in the plurality of groove patterns. The plurality of filling resin patterns are arranged to be spaced apart from each other along the first direction. The plurality of groove patterns extends in a second direction crossing the first direction. Each of the plurality of filling resin patterns has varying heights along the second direction in which mountain portions and valley portions are alternately arranged along the second direction.

In an embodiment, an angle between a line connecting adjacent mountain portions of adjacent filling resin patterns of the plurality of filling resin patterns that are adjacent to each other along the first direction and the first direction is greater than 0° and less than 90°.

In an embodiment, an angle between a line connecting adjacent mountain portions of adjacent filling resin patterns of the plurality of filling resin patterns that are adjacent to each other along the first direction and the second direction is greater than 0° and less than 90°.

In an embodiment, the first direction and the second direction are perpendicular to each other.

In an embodiment, a height difference between the mountain portions and the valley portions of each of the plurality of filling resin pattern is in a range of about 5 to about 15 μm.

In an embodiment, the plurality of filling resin patterns includes a first filling resin pattern disposed in a first surface of the window and a second filling resin pattern disposed in a second surface of the window that is a surface opposite to the first surface in a thickness direction of the window and faces the display panel, and a mountain portion of the first filling resin pattern and a mountain portion of the second filling resin pattern are positioned on a same axis along the thickness direction of the window.

In an embodiment, the plurality of filling resin patterns includes a first filling resin pattern disposed in a first surface of the window and a second filling resin pattern disposed in a second surface of the window that is a surface opposite to the first surface in a thickness direction of the window and faces the display panel, and a mountain portion of the first filling resin pattern and a valley portion of the second filling resin pattern are positioned on a same axis along the thickness direction of the window.

In an embodiment, the plurality of filling resin patterns includes a first filling resin pattern disposed in a first surface of the window and a second filling resin pattern disposed in a second surface of the window that is a surface opposite to the first surface in a thickness direction of the window and faces the display panel, and the first filling resin pattern and the second filling resin pattern have shapes symmetrical to each other.

In an embodiment, the plurality of filling resin patterns includes a first filling resin pattern disposed in a first surface of the window and a second filling resin pattern disposed in a second surface of the window that is a surface opposite to the first surface in a thickness direction of the window and faces the display panel, and the first filling resin pattern and the second filling resin pattern have shapes asymmetrical to each other.

In an embodiment, the plurality of filling resin patterns includes a plurality of first filling resin patterns disposed in a first surface of the window and a plurality of second filling resin patterns disposed in a second surface of the window that is a surface opposite to the first surface in a thickness direction of the window and faces the display panel, and a pitch between adjacent mountain portions in the plurality of first filling resin patterns and a pitch between adjacent mountain portions in the plurality of second filling resin patterns are equal to each other.

In an embodiment, mountain portions of adjacent filling resin patterns of the plurality of filling resin patterns that are adjacent to each other along the first direction have different heights from each other and form a step therebetween.

In an embodiment, a connection line connecting the mountain portions and the valley portions of each of the plurality of filling resin patterns to each other along the second direction has a wavy shape.

In an embodiment, the plurality of filling resin patterns includes a first filling resin pattern disposed in a first surface of the window and a second filling resin pattern disposed in a second surface of the window that is a surface opposite to the first surface in a thickness direction of the window and faces the display panel, and the first filling resin pattern has a shape that protrudes from a surface of the first surface towards the second surface, the second filling resin pattern has a shape that protrudes from a surface of the second surface towards the first surface, and the first filling resin pattern and the second filling resin pattern are alternately arranged along the first direction.

In an embodiment, the plurality of filling resin patterns include one or more filling resins selected from a urethane-based resin, an epoxy-based resin, a polyester-based resin, a polyether-based resin, an acrylate-based resin, an acrylonitrile-butadiene-styrene (ABS) resin, and rubber.

In an embodiment, the plurality of groove patterns include a plurality of first concave grooves defined in a first surface of the window and a plurality of second concave grooves defined in a second surface of the window that is a surface opposite to the first surface and faces the display panel, and the plurality of first concave grooves and the plurality of second concave grooves are alternately arranged.

In an embodiment, the plurality of groove patterns each have a semicircular cross-sectional shape or a polygonal cross-sectional shape.

According to an embodiment of the present disclosure, a transparent panel for a display device, comprises a transparent panel including a pattern portion including a plurality of groove patterns recessed in a thickness direction from one surface, a first non-pattern portion positioned on a first side of the pattern portion in a first direction and having one surface that is flat, and a second non-pattern portion positioned on an opposite second side of the pattern portion in the first direction and having one surface that is flat, and a plurality of filling resin patterns at least partially filled in the plurality of groove patterns of the pattern portion. The plurality of filling resin patterns is arranged to be spaced apart from each other along the first direction. The plurality of groove patterns extends in a second direction crossing the first direction. Each of the plurality of filling resin patterns has varying heights along the second direction in which mountain portions and valley portions are alternately arranged along the second direction. An angle between a line connecting adjacent mountain portions of adjacent filling resin patterns of the plurality of filling resin patterns that are adjacent to each other along the first direction and the first direction is greater than 0° and less than 90°.

In an embodiment, an angle between the line connecting the adjacent mountain portions of the adjacent filling resin patterns and the second direction is greater than 0° and less than 90°.

In an embodiment, the first direction and the second direction are perpendicular to each other.

In an embodiment, a height difference between the mountain portions and the valley portions of each of the plurality of filling resin patterns is in a range of about 5 to about 15 μm.

According to an embodiment of the present disclosure, a smartphone includes a display panel including a folding area. A window is disposed on the display panel and includes an upper surface and a lower surface. The window includes a pattern portion disposed at a position overlapping the folding area. The pattern portion includes a plurality of first concave grooves recessed towards the lower surface of the window and a plurality of second concave grooves recessed towards the upper surface of the window. The plurality of first concave grooves and the plurality of second concave grooves are alternately arranged along a first direction. Each of the plurality of first concave grooves and the plurality of second concave grooves extends in a second direction crossing the first direction. A plurality of first filling resin patterns is disposed in the plurality of first concave grooves and a plurality of second filling resin patterns is disposed in the plurality of second concave grooves. At least one of the plurality of first filling resin patterns and the plurality of second filling resin patterns has varying heights along the second direction, and includes mountain portions and valley portions alternately arranged along the second direction.

In an embodiment, an angle between a line connecting adjacent mountain portions of adjacent filling resin patterns of the at least one of the plurality of first filling resin patterns and the plurality of second filling resin patterns and the first direction is in a range of about 3° to about 15°.

In an embodiment, a line connecting adjacent first filling resin patterns of the plurality of first filling resin patterns that are adjacent along the first direction has a curved line shape. A line connecting adjacent second filling resin patterns of the plurality of second filling resin patterns that are adjacent along the first direction has a straight line shape.

In an embodiment, the line connecting the adjacent first filling resin patterns has a parabola shape.

In an embodiment, a line connecting adjacent first filling resin patterns of the plurality of first filling resin patterns that are adjacent along the first direction has a curved line shape. A line connecting adjacent second filling resin patterns of the plurality of second filling resin patterns that are adjacent along the first direction has the curved line shape.

With a display device according to an embodiment, it is possible to prevent deterioration of screen quality by reducing a moiré phenomenon.

The effects of the present disclosure are not limited to the aforementioned effects, and various other effects are included in the present specification.

### BRIEF DESCRIPTION OF THE DRAWINGS

The above and other aspects and features of embodiments of the present disclosure will become more apparent by describing in detail non-limiting embodiments thereof with reference to the attached drawings, in which:

FIG. 1 is a perspective view illustrating an unfolded state of a display device according to an embodiment of the present disclosure;

FIG. 2 is a perspective view illustrating a folded state of the display device of FIG. 1 according to an embodiment of the present disclosure;

FIG. 3 is an exploded perspective view illustrating the display device according to an embodiment of the present disclosure;

FIG. 4 is a side view illustrating the display device according to an embodiment of the present disclosure;

FIG. 5 is a cross-sectional view illustrating an example of a display panel of FIGS. 3 and 4 in detail according to an embodiment of the present disclosure;

FIG. 6 is an enlarged cross-sectional view of a section where a pattern portion of FIGS. 3 and 4 is formed according to an embodiment of the present disclosure;

FIG. 7 is an enlarged cross-sectional view of a portion of the pattern portion of FIG. 6 according to an embodiment of the present disclosure;

FIG. 8 is an enlarged cross-sectional view of first and second concave grooves of FIG. 7 according to an embodiment of the present disclosure;

FIG. 9 is an enlarged cross-sectional view illustrating the first and second concave grooves of FIG. 8 and filling resin patterns filled in the first and second concave grooves according to an embodiment of the present disclosure;

FIG. 10 is a side cross-sectional view of a first filling resin pattern taken along line X-X1 in FIG. 9 according to an embodiment of the present disclosure;

FIG. 11 is a side perspective view of the first filling resin pattern of FIG. 9 and is a schematic view of the first filling resin pattern according to an embodiment of the present disclosure;

FIG. 12 is a side perspective view of the first filling resin pattern of FIG. 9 according to an embodiment of the present disclosure;

FIG. 13 is a plan view of the first and second concave grooves and first and second filling resin patterns of FIG. 9 according to an embodiment of the present disclosure;

FIG. 14 is a graph illustrating moiré evaluation results according to steps between a mountain portion and a valley portion of FIG. 9 according to an embodiment of the present disclosure;

FIG. 15 is a photograph illustrating a state in which a moiré occurs when a height difference between the mountain portion and the valley portion of FIG. 9 is less than 2 according to an embodiment of the present disclosure; and

FIGS. 16 to 20 are enlarged cross-sectional views illustrating pattern portions according to embodiments of the present disclosure.

### DETAILED DESCRIPTION OF EMBODIMENTS

The present invention will now be described more fully hereinafter with reference to the accompanying drawings, in which non-limiting embodiments of the present disclosure are shown. The present disclosure may, however, be embodied in different forms and should not be construed as limited to the described embodiments set forth herein.

It will also be understood that when a layer or element is referred to as being “on” another layer, element or substrate, it can be directly on the other layer, element or substrate, or intervening layers may also be present. When a layer or element is referred to as being “directly on” another layer, element or substrate, no intervening layers may be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

Each of the features of the various embodiments of the present disclosure may be combined or combined with each other, in part or in whole, and technically various interlocking and driving are possible. Each embodiment may be implemented independently of each other or may be implemented together in an association.

Hereinafter, embodiments will be described with reference to the accompanying drawings.

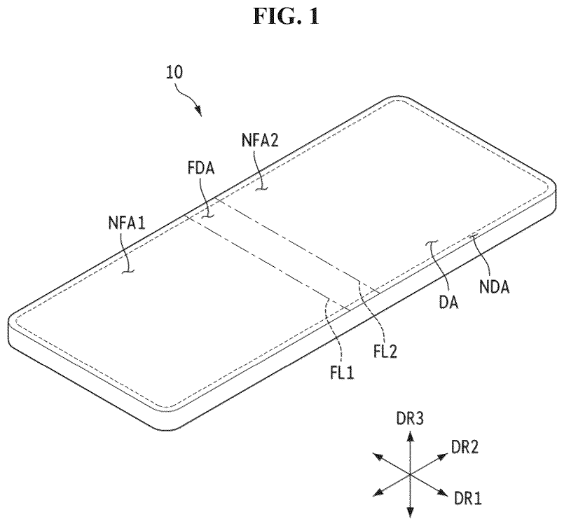

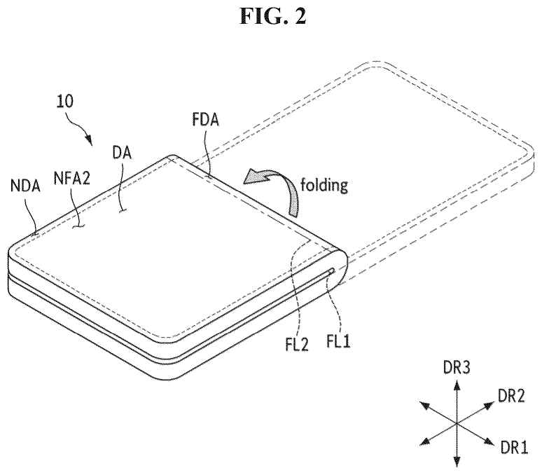

FIG. 1 is a perspective view illustrating an unfolded state of a display device according to an embodiment, and FIG. 2 is a perspective view illustrating a folded state of the display device of FIG. 1.

Here, an unfolded state, which is a first state of a display device 10 that is not bent at folding lines FL1 and FL2 and is unfolded, is illustrated in FIG. 1, and a folded state, which is a second state of the display device 10 that is bent at the folding lines FL1 and FL2, is illustrated in FIG. 2.

Referring to FIGS. 1 and 2, the display device 10 according to an embodiment is a device that displays at least one moving image and/or at least one still image, and may be used as a display screen of various products such as televisions, laptop computers, monitors, billboards, and the Internet of Things (IoT) devices as well as portable electronic devices such as mobile phones, smartphones, tablet personal computers (PCs), smart watches, watch phones, mobile communication terminals, electronic notebooks, electronic books, portable multimedia players (PMPs), navigation devices, and ultra mobile PCs (UMPCs). The smartphone may include a display panel, a touch panel and a wireless communication device. However, embodiments of the present disclosure are not necessarily limited thereto.

Referring to FIGS. 1 and 2, a transverse direction DR1 is a direction parallel to one side of the display device 10 in plan view, and may be a transverse direction of the display device 10. In an embodiment, a longitudinal direction DR2 is a direction parallel to the other side of the display device 10 in direct contact with one side of the display device 10 in plan view, and may be a longitudinal direction of the display device 10. A third direction DR3 may be a thickness direction of the display device 10. In an embodiment, the transverse direction DR1 and the longitudinal direction DR2 may cross each other. For example, in some embodiments the transverse and longitudinal directions DR1, DR2 may be perpendicular to each other.

The display device 10 may have a quadrangular shape such as a rectangular shape in a plan view. Each of corners of the display device 10 may have a right-angle shape in plan view or a round shape in plan view. In an embodiment, a front surface of the display device 10 may include two short sides disposed in the transverse direction DR1 and two long sides disposed in the longitudinal direction DR2.

The display device 10 includes a display area DA and a non-display area NDA. In an embodiment, a shape of the display area DA in plan view may follow the shape of the display device 10 in a plan view. For example, in an embodiment in which the shape of the display device 10 in a plan view is the rectangular shape, the shape of the display area DA in plan view may also be a rectangular shape.

The display area DA may be an area displaying an image by including a plurality of pixels. The non-display area NDA may be an area that does not display an image and does not include pixels. The non-display area NDA may be disposed around the display area DA (e.g., in a plan view). For example, in an embodiment, the non-display area NDA may be disposed to surround the display area DA (e.g., in a plan view). However, embodiments of the present disclosure are not necessarily limited thereto. For example, in an embodiment the display area DA may be partially surrounded by the non-display area NDA.

The display device 10 may be maintained in both a first state, which is the unfolded state, and a second state, which is the folded state. In an embodiment, the display device 10 may be folded in an in-folding manner in which the display areas DA face each other as illustrated in FIG. 2. In this embodiment, front surfaces of the display device 10 may face each other when the display device 10 is folded. Alternatively, the display device 10 may be folded in an out-folding manner so that rear surfaces thereof face each other.

In an embodiment, the display device 10 may include a folding area FDA, a first non-folding area NFA1, and a second non-folding area NFA2. The folding area FDA may be an area where the display device 10 is bent or folded, and the first non-folding area NFA1 and the second non-folding area NFA2 may be areas where the display device 10 is not bent or folded. For example, the first non-folding area NFA1 and the second non-folding area NFA2 may be flat areas of the display device 10.

The first non-folding area NFA1 may be disposed on one side, for example, the lower side, of the folding area FDA (e.g., in the second direction DR2). The second non-folding area NFA2 may be disposed on the other side, for example, the upper side, of the folding area FDA (e.g., in the second direction DR2). The folding area FDA is an area defined by a first folding line FL1 and a second folding line FL2, and may be an area where the display device 10 is bent with a predetermined curvature. The first folding line FL1 may be a boundary between the folding area FDA and the first non-folding area NFA1, and the second folding line FL2 may be a boundary between the folding area FDA and the second non-folding area NFA2.

In an embodiment, each of the display area DA and the non-display area NDA may overlap at least one of the folding area FDA, the first non-folding area NFA1, and the second non-folding area NFA2. It has been illustrated in FIGS. 1 and 2 that each of the display area DA and the non-display area NDA overlaps the folding area FDA, the first non-folding area NFA1, and the second non-folding area NFA2.

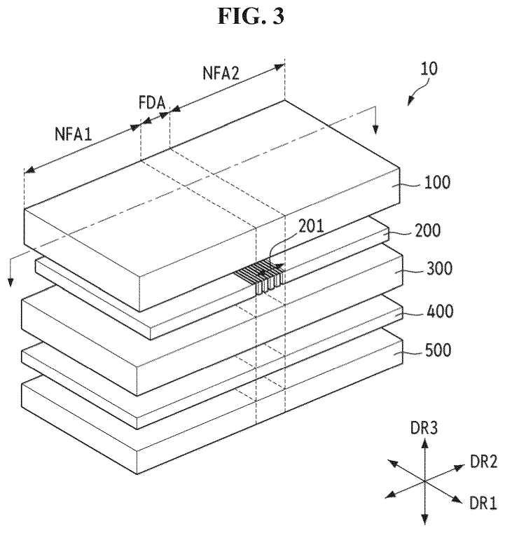

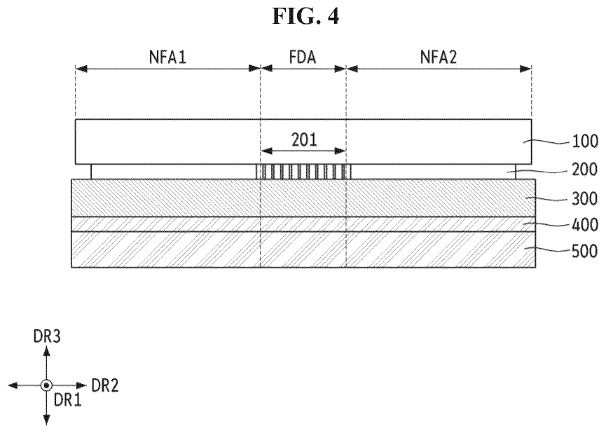

FIG. 3 is an exploded perspective view illustrating the display device according to an embodiment, and FIG. 4 is a side view illustrating the display device according to an embodiment.

Referring to FIGS. 3 and 4, the display device 10 according to an embodiment may include an upper protection member 100, a window 200, a first adhesive member 300, a display panel 400, and a panel protection member 500.

The upper protection member 100 may be disposed on a front surface of the window 200 (e.g., in the third direction DR3). The upper protection member 100 may be attached to the front surface of the window 200. In an embodiment, the upper protection member 100 may perform at least one of a scattering prevention function of the window 200, a shock absorption function, a chopping prevention function, a fingerprint prevention function, and a glare prevention function.

A light blocking pattern may be formed on a rear surface of the upper protection member 100. The light blocking pattern may be disposed at an edge of the upper protection member 100 or be disposed adjacent to the edge of the upper protection member 100. The light blocking pattern may include a light blocking material capable of blocking light. For example, in an embodiment the light blocking pattern may be made of an inorganic black pigment such as carbon black, an organic black pigment, or an opaque metal material.

The window 200 may be attached onto a front surface of the display panel 400 by the first adhesive member 300. The window 200 may be made of a transparent material such as glass or plastic. For example, in an embodiment the window 200 may be ultra-thin glass (UTG) having a thickness less than or equal to about 0.1 mm or a transparent polyimide film. However, embodiments of the present disclosure are not necessarily limited thereto. The window 200 may be a transparent panel.

In an embodiment, the first adhesive member 300 may be positioned between the window 200 and the display panel 400 (e.g., in the third direction DR3) to attach the window 200 to the display panel 400, and may be a transparent adhesive film or a transparent adhesive resin.

The display panel 400 may be a panel that displays an image. In an embodiment, the display panel 400 may be an organic light emitting display panel including an organic light emitting layer, a quantum dot light emitting display panel including a quantum dot light emitting layer, an inorganic light emitting display panel using inorganic semiconductor elements as light emitting elements, and a micro light emitting display panel using micro light emitting diodes as light emitting elements. Hereinafter, it will be mainly described that the display panel 400 is an organic light emitting display panel. However, embodiments of the present disclosure are not necessarily limited thereto.

The panel protection member 500 may be disposed on a rear surface of the display panel 400. The panel protection member 500 may serve to support the display panel 400 and protect the rear surface of the display panel 400. The panel protection member 500 may be made of plastic such as polyethylene terephthalate (PET) or polyimide or glass. It has been illustrated in embodiments of FIGS. 3 and 4 that the panel protection member 500 is disposed in the folding area FDA of the display device 10. However, embodiments of the present disclosure are not necessarily limited thereto. For example, in some embodiments the panel protection member 500 may be removed in the folding area FDA of the display device 10 so that the display device 10 may be smoothly folded.

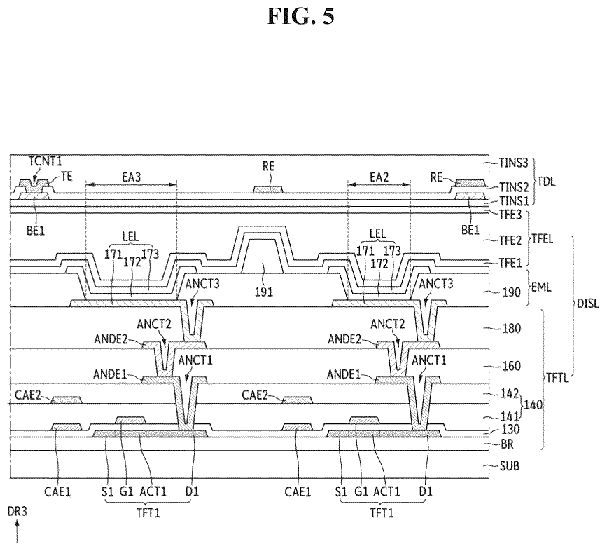

FIG. 5 is a cross-sectional view illustrating an example of a display panel of FIGS. 3 and 4 in detail.

Referring to FIG. 5, in the display panel 400, a display layer DISL may be disposed on a substrate SUB (e.g., in the third direction DR3).

In an embodiment, the display layer DISL may include a thin film transistor layer TFTL, a light emitting element layer EML, and an encapsulation layer TFEL.

The thin film transistor layer TFTL may be disposed on the substrate SUB (e.g., disposed directly thereon in the third direction DR3). In an embodiment, the thin film transistor layer TFTL may include a barrier film BR, thin film transistors TFT1, first capacitor electrodes CAE1, second capacitor electrodes CAE2, first anode connection electrodes ANDE1, second anode connection electrodes ANDE2, a gate insulating film 130, a first interlayer insulating film 141, a second interlayer insulating film 142, a first planarization film 160, and a second planarization film 180.

The substrate SUB may be made of an insulating material such as a polymer resin. For example, in an embodiment the substrate SUB may be made of polyimide. The substrate SUB may be a flexible substrate that may be bent, folded, and rolled.

The barrier film BR may be disposed on the substrate SUB (e.g., disposed directly thereon in the third direction DR3). The barrier film BR is a film for protecting thin film transistors of the thin film transistor layer TFTL and light emitting layers 172 of the light emitting element layer EML from moisture permeating through the substrate SUB vulnerable to moisture permeation. In an embodiment, the barrier film BR may include a plurality of inorganic films that are alternately stacked (e.g., in the third direction DR3). For example, in an embodiment the barrier film BR may be formed as multiple films in which one or more inorganic films of a silicon nitride layer, a silicon oxynitride layer, a silicon oxide layer, a titanium oxide layer, and an aluminum oxide layer are alternately stacked.

The thin film transistors TFT1 may be disposed on the barrier film BR (e.g., in the third direction DR3).

Active layers ACT1 of the thin film transistors TFT1 may be disposed on the barrier film BR (e.g., disposed directly thereon in the third direction DR3). In an embodiment, the active layer ACT1 of the thin film transistor TFT1 may include polycrystalline silicon, single crystal silicon, low-temperature polycrystalline silicon, amorphous silicon, or an oxide semiconductor.

The active layer ACT1 may include a channel region CHA1, a source region S1, and a drain region D1. The channel region CHA1 may be a region overlapping a gate electrode G1 in the third direction DR3, which is a thickness direction of the substrate SUB. The source region S1 may be disposed on one side of the channel region CHA1, and the drain region D1 may be disposed on the other side of the channel region CHA1. The source region S1 and the drain region D1 may be regions that do not overlap the gate electrode G1 in the third direction DR3. In an embodiment, the source region S1 and the drain region D1 may be regions having conductivity by doping a silicon semiconductor or an oxide semiconductor with ions or impurities.

The gate insulating film 130 may be disposed on (e.g., disposed directly thereon) the active

layer ACT1 of the thin film transistor TFT1. In an embodiment, the gate insulating film 130 may be formed as an inorganic film such as a silicon nitride layer, a silicon oxynitride layer, a silicon oxide layer, a titanium oxide layer, or an aluminum oxide layer.

The gate electrodes G1 of the thin film transistors TFT1 and the first capacitor electrodes CAE1 may be disposed on the gate insulating film 130 (e.g., disposed directly thereon). The gate electrode G1 may overlap the active layer ACT1 in the third direction DR3. It has been illustrated in FIG. 5 that the gate electrode G1 and the first capacitor electrode CAE1 are disposed to be spaced apart from each other, but the gate electrode G1 and the first capacitor electrode CAE1 may be connected to and formed integrally with each other. In an embodiment, each of the gate electrode G1 and the first capacitor electrode CAE1 may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The first interlayer insulating film 141 may be disposed on the gate electrodes G1 of the thin film transistors TFT1 and the first capacitor electrodes CAE1. In an embodiment, the first interlayer insulating film 141 may be formed as an inorganic film such as a silicon nitride layer, a silicon oxynitride layer, a silicon oxide layer, a titanium oxide layer, or an aluminum oxide layer. The first interlayer insulating film 141 may be formed as a plurality of inorganic films.

The second capacitor electrodes CAE2 may be disposed on the first interlayer insulating film 141 (e.g., disposed directly thereon in the third direction DR3). The second capacitor electrode CAE2 may overlap the first capacitor electrode CAE1 in the third direction DR3. In addition, in an embodiment in which the gate electrode G1 and the first capacitor electrode CAE1 are formed integrally with each other, the second capacitor electrode CAE2 may overlap the gate electrode G1 in the third direction DR3. Since the first interlayer insulating film 141 has a predetermined dielectric constant, a capacitor may be formed by the first capacitor electrode CAE1, the second capacitor electrode CAE2, and the first interlayer insulating film 141 disposed between the first capacitor electrode CAE1 and the second capacitor electrode CAE2. In an embodiment, the second capacitor electrode CAE2 may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The second interlayer insulating film 142 may be disposed on the second capacitor electrodes CAE2 (e.g., disposed directly thereon in the third direction DR3). The second interlayer insulating film 142 may be formed as an inorganic film such as a silicon nitride layer, a silicon oxynitride layer, a silicon oxide layer, a titanium oxide layer, or an aluminum oxide layer. In an embodiment, the second interlayer insulating film 142 may be formed as a plurality of inorganic films.

The first anode connection electrodes ANDE1 may be disposed on the second interlayer insulating film 142 (e.g., disposed directly thereon in the third direction DR3). In an embodiment, the first anode connection electrode ANDE1 may be connected to the drain region D1 of the thin film transistor TFT1 through a first connection contact hole ANCT1 penetrating through the gate insulating film 130, the first interlayer insulating film 141, and the second interlayer insulating film 142. In an embodiment, the first anode connection electrode ANDE1 may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The first planarization film 160 for planarizing a step due to the thin film transistors TFT1 may be disposed on (e.g., disposed directly thereon) the first anode connection electrodes ANDE1. In an embodiment, the first planarization film 160 may be formed as an organic film made of an acrylic resin, an epoxy resin, a phenolic resin, a polyamide resin, a polyimide resin, or the like.

The second anode connection electrodes ANDE2 may be disposed on the first planarization film 160 (e.g., disposed directly thereon in the third direction DR3). In an embodiment, the second anode connection electrode ANDE2 may be connected to the first anode connection electrode ANDE1 through a second connection contact hole ANCT2 penetrating through the first planarization film 160. In an embodiment, the second anode connection electrode ANDE2 may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The second planarization film 180 may be disposed on (e.g. disposed directly thereon) the second anode connection electrodes ANDE2. In an embodiment, the second planarization film 180 may be formed as an organic film made of an acrylic resin, an epoxy resin, a phenolic resin, a polyamide resin, a polyimide resin, or the like.

The light emitting element layer EML including light emitting elements LEL and a bank 190 may be disposed on the second planarization film 180. In an embodiment, each of the light emitting elements LEL includes a pixel electrode 171, a light emitting layer 172, and a common electrode 173.

The pixel electrode 171 may be disposed on the second planarization film 180 (e.g., disposed directly thereon in the third direction DR3). In an embodiment, the pixel electrode 171 may be connected to the second anode connection electrode ANDE2 through a third connection contact hole ANCT3 penetrating through the second planarization film 180.

In an embodiment having a top emission structure in which light is emitted towards the common electrode 173 based on the light emitting layer 172, the pixel electrode 171 may be made of a metal material having high reflectivity, such as a stacked structure (Ti/Al/Ti) of aluminum (Al) and titanium (Ti), a stacked structure (ITO/Al/ITO) of aluminum (Al) and indium tin oxide (ITO), a stacked structure (ITO/Ag/ITO) of silver (Ag) and ITO, an APC alloy, and a stacked structure (ITO/APC/ITO) of an APC alloy and ITO. The APC alloy is an alloy of silver (Ag), palladium (Pd), and copper (Cu).

The bank 190 may be formed to partition the pixel electrodes 171 on the second planarization film 180, to define a first light emitting portion EA1, a second light emitting portion EA2, a third light emitting portion EA3, and a fourth light emitting portion EA4. The bank 190 may be disposed to cover edges of the pixel electrode 171. In an embodiment, the bank 190 may be formed as an organic film made of an acrylic resin, an epoxy resin, a phenolic resin, a polyamide resin, a polyimide resin, or the like.

In an embodiment, each of the first light emitting portion EA1, the second light emitting portion EA2, the third light emitting portion EA3, and the fourth light emitting portion EA4 refers to an area where the pixel electrode 171, the light emitting layer 172, and the common electrode 173 are sequentially stacked and holes from the pixel electrode 171 and electrons from the common electrode 173 are recombined with each other in the emission layer 172 to emit light.

The light emitting layer 172 may be disposed on the pixel electrode 171 and the bank 190. In an embodiment, the light emitting layer 172 may include an organic material to emit light of a predetermined color. For example, in an embodiment the light emitting layer 172 includes a hole transporting layer, an organic material layer, and an electron transporting layer.

The common electrode 173 may be disposed on the light emitting layer 172 (e.g., in the third direction DR3). The common electrode 173 may be disposed to cover the light emitting layer 172. In an embodiment, the common electrode 173 may be a common layer commonly formed in the first light emitting portion EA1, the second light emitting portion EA2, the third light emitting portion EA3, and the fourth light emitting portion EA4. In an embodiment, a capping layer may be formed on the common electrode 173.

In an embodiment having the top emission structure, the common electrode 173 may be made of a transparent conductive material (TCO) such as ITO or indium zinc oxide (IZO) capable of transmitting light therethrough or a semi-transmissive conductive material such as magnesium (Mg), silver (Ag), or an alloy of magnesium (Mg) and silver (Ag). In an embodiment in which the common electrode 173 is made of the semi-transmissive conductive material, light emission efficiency may be increased by a micro cavity.

A spacer 191 may be disposed on the bank 190 (e.g., disposed directly thereon in the third

direction DR3). The spacer 191 may serve to support a mask during a manufacturing process of manufacturing the light emitting layer 172. In an embodiment, the spacer 191 may be formed as an organic film made of an acrylic resin, an epoxy resin, a phenolic resin, a polyamide resin, a polyimide resin, or the like.

The encapsulation layer TFEL may be disposed on the common electrode 173 (e.g., disposed directly thereon in the third direction DR3). In an embodiment, the encapsulation layer TFEL includes at least one inorganic film to prevent oxygen or moisture from permeating into the light emitting element layer EML. In addition, the encapsulation layer TFEL includes at least one organic film to protect the light emitting element layer EML from foreign substances such as dust. For example, in an embodiment the encapsulation layer TFEL includes a first encapsulation inorganic film TFE1, an encapsulation organic film TFE2, and a second encapsulation inorganic film TFE3. However, embodiments of the present disclosure are not necessarily limited thereto.

The first encapsulation inorganic film TFE1 may be disposed on the common electrode 173 (e.g., disposed directly thereon in the third direction DR3), the encapsulation organic film TFE2 may be disposed on the first encapsulation inorganic film TFE1 (e.g., disposed directly thereon in the third direction DR3), and the second encapsulation inorganic film TFE3 may be disposed on the encapsulation organic film TFE2 (e.g., disposed directly thereon in the third direction DR3). In an embodiment, each of the first encapsulation inorganic film TFE1 and the second encapsulation inorganic film TFE3 may be formed as multiple films in which one or more inorganic films of a silicon nitride layer, a silicon oxynitride layer, a silicon oxide layer, a titanium oxide layer, and an aluminum oxide layer are alternately stacked (e.g., in the third direction DR3). The encapsulation organic film TFE2 may be an organic film made of an acrylic resin, an epoxy resin, a phenolic resin, a polyamide resin, a polyimide resin, or the like.

In an embodiment, a touch sensing layer TDL may be disposed on the encapsulation layer TFEL (e.g., disposed directly thereon in the third direction DR3). For example, in an embodiment the touch sensing layer TDL includes a first touch insulating film TINS1, connection electrodes BE1, a second touch insulating film TINS2, driving electrodes TE, sensing electrodes RE, and a third touch insulating film TINS3.

The first touch insulating film TINS1 may be disposed on the encapsulation layer TFEL (e.g., disposed directly thereon in the third direction DR3). In an embodiment, the first touch insulating film TINS1 may be formed as an inorganic film such as a silicon nitride layer, a silicon oxynitride layer, a silicon oxide layer, a titanium oxide layer, or an aluminum oxide layer.

The connection electrodes BE1 may be disposed on the first touch insulating film TINS1 (e.g., disposed directly thereon in the third direction DR3). In an embodiment, the connection electrode BE may be formed as a single layer or multiple layers made of any one of molybdenum

(Mo), aluminum (Al), chromium (Cr), gold (Au), titanium (Ti), nickel (Ni), neodymium (Nd), and copper (Cu), or alloys thereof.

The second touch insulating film TINS2 is disposed on (e.g., disposed directly thereon) the connection electrodes BE1. In an embodiment, the second touch insulating film TINS2 may be formed as an inorganic film such as a silicon nitride layer, a silicon oxynitride layer, a silicon oxide layer, a titanium oxide layer, or an aluminum oxide layer. Alternatively, the second touch insulating film TINS2 may be formed as an organic film made of an acrylic resin, an epoxy resin, a phenolic resin, a polyamide resin, a polyimide resin, or the like.

The driving electrodes TE and the sensing electrodes RE may be disposed on the second touch insulating film TINS2 (e.g., disposed directly thereon in the third direction DR3). Further, in an embodiment, in addition to the driving electrodes TE and the sensing electrodes RE, dummy patterns, first touch driving lines, second touch driving lines, and touch sensing lines may be disposed on the second touch insulating film TINS2. In an embodiment, each of the driving electrodes TE and the sensing electrodes RE may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The driving electrode TE and the sensing electrode RE may overlap the connection electrodes BE1 in the third direction DR3. In an embodiment, the driving electrode TE may be connected to the connection electrode BE through a touch contact hole TCNT1 penetrating through the second touch insulating film TINS2.

The third touch insulating film TINS3 is formed on (e.g., disposed directly thereon) the driving electrodes TE and the sensing electrodes RE. The third touch insulating film TINS3 may planarize a step formed due to the driving electrodes TE, the sensing electrodes RE, and the connection electrodes BE1. In an embodiment, the third touch insulating film TINS3 may be formed as an organic film made of an acrylic resin, an epoxy resin, a phenolic resin, a polyamide resin, a polyimide resin, or the like.

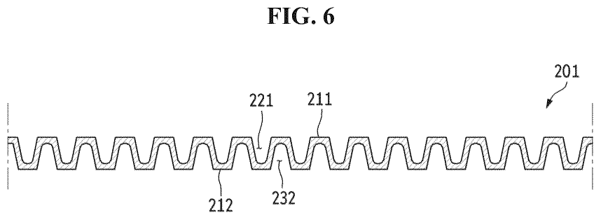

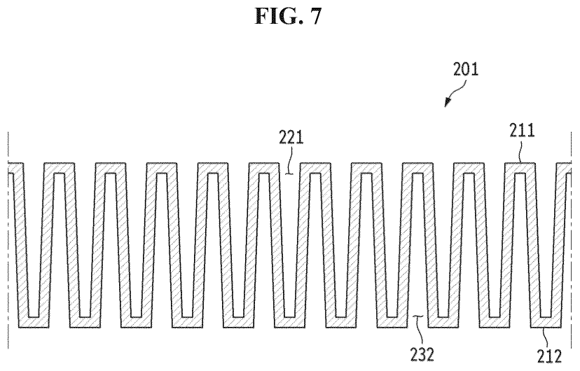

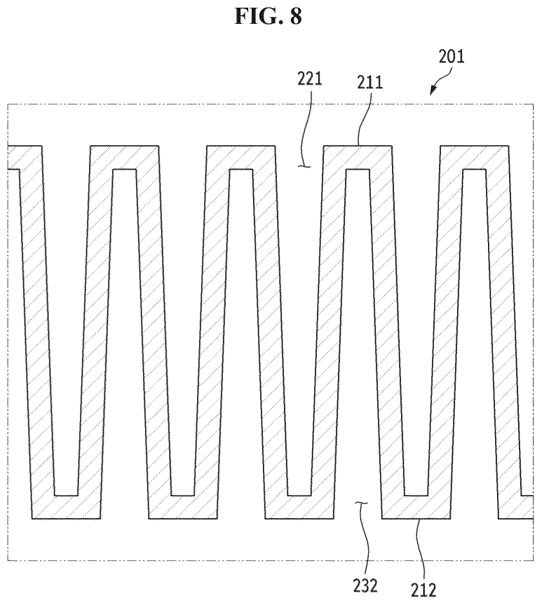

FIG. 6 is an enlarged cross-sectional view of a section where a pattern portion of FIGS. 3 and 4 is formed, FIG. 7 is an enlarged cross-sectional view of a portion of the pattern portion of FIG. 6, and FIG. 8 is an enlarged cross-sectional view of first and second concave grooves of FIG. 7.

Referring to FIGS. 6 and 7, in an embodiment the window 200 may include a window upper surface 211 that faces the upper protection member 100 and a window lower surface 212 that is a surface opposite to the window upper surface 211 and faces the display panel 400 to which the first adhesive member 300 is attached.

The window 200 may include a pattern portion 201 disposed at a position corresponding to the folding area FDA. For example, in an embodiment the pattern portion 201 may be positioned in the window 200 in a portion overlapping the folding area FDA (e.g., in the third direction DR3).

The pattern portion 201 may be positioned to overlap the folding area FDA (e.g., in the third direction DR3), and may include groove patterns 221 and 232 and filling resin patterns 241 and 242 filled inside the groove patterns 221 and 232. In an embodiment, the pattern portion 201 may be positioned at a central portion of the window 200, such as at a central portion of the window 200 based on the longitudinal direction DR2, which is a first direction. Referring to FIG. 3, the pattern portion 201 may be positioned in parallel with the transverse direction DR1, which is a second direction. However, embodiments of the present disclosure are not necessarily limited thereto and the pattern portion 201 may also be disposed to be inclined with respect to the transverse direction DR1. In an embodiment, the window 200 may also include a first non-pattern portion positioned on a first side of the pattern portion 201 (e.g., in the second direction DR2) and having one surface (e.g., an upper surface) that is flat and a second non-pattern portion positioned on an opposite second side of the pattern portion 201 (e.g., in the second direction DR2) and having one surface (e.g., an upper surface) that is flat.

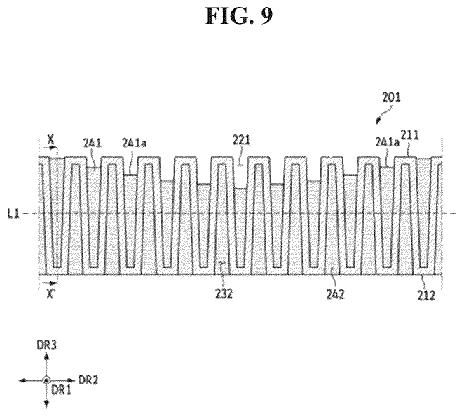

Referring to FIG. 8, the groove patterns 221 and 232 may include a plurality of first concave grooves 221 that are continuously disposed and a plurality of second concave grooves 232 that are continuously disposed in a reverse shape to the first concave grooves 221 based on a first line L1 (see FIG. 9) to be described later. However, arrangement and disposition states of the first and second concave grooves 232 are not necessarily limited thereto.

In an embodiment, the groove patterns 221 and 232 having such a configuration may have a wavy shape in which semicircular or trapezoidal shapes are continuously connected to each other based on a cross section of FIG. 6. However, embodiments of the present disclosure are not necessarily limited thereto. A cross-sectional shape of the groove patterns 221 and 232 may be a triangular wavy shape or various polygonal wavy shapes such as a quadrangular shape, a pentagonal shape, a hexagon shape, etc.

The plurality of first concave grooves 221 may be formed in the window upper surface 211, and may be formed to be spaced apart from each other along a horizontal direction, which is a surface direction of the window upper surface 211.

In an embodiment, the number of first concave grooves 221 may be odd for the purpose of symmetry of a folded state when the window 200 is folded. However, embodiments of the present disclosure are not necessarily limited thereto. In addition, in an embodiment the number of first concave grooves 221 may be greater than the number of second concave grooves 232. However, embodiments of the present disclosure are not necessarily limited thereto.

In an embodiment, the plurality of second concave grooves 232 may be formed in the window lower surface 212, and may be formed to be spaced apart from each other along the horizontal direction, which is a surface direction of the window lower surface 212. In an embodiment, the number of second concave grooves 232 may be less than the number of first concave grooves 221. However, embodiments of the present disclosure are not necessarily limited thereto.

In an embodiment, the plurality of first concave grooves 221 and the plurality of second concave grooves 232 may be alternately disposed one by one so as not to overlap each other (e.g., in a plan view).

Each first concave groove 221 may be positioned in the window upper surface 211 and may have a concave groove shape in which it is recessed towards the window lower surface 212, and each second concave groove 232 may be positioned in the window lower surface 212 and may have a concave groove shape in which it is recessed towards the window upper surface 211.

In an embodiment, each first concave groove 221 may have a semicircular cross-sectional shape or a polygonal cross-sectional shape such as a trapezoidal shape. However, each first concave groove 221 is not necessarily limited thereto, and may be formed in various shapes.

In an embodiment, each second concave groove 232 may have the same shape as the first concave groove 221 and have a semicircular cross-sectional shape or a polygonal cross-sectional shape such as a trapezoidal shape, but may be disposed in a reverse cross-sectional shape to the first concave groove 221 based on the first line L1. However, a shape of each second concave groove 232 is not necessarily limited to the semicircular cross-sectional shape or the polygonal cross-sectional shape such as the trapezoidal shape, and may also be various polygonal cross-sectional shapes. In addition, in some embodiments the second concave grooves 232 may also be disposed alternately with the first concave grooves 221 in a different shape from the first concave grooves 221.

The first and second concave grooves 221 and 232 may be formed in the window upper surface 211 and the window lower surface 212, respectively, and each of the first and second concave grooves 221 and 232 may include openings opened to each of the window upper surface 211 and the window lower surface 212.

In an embodiment, the first and second concave grooves 221 and 232 may be formed using a laser induced deep etching (LIDE) method. The LIDE method may include irradiating the window 200 with a laser and etching an area irradiated with the laser. For example, in an embodiment the etching may be wet etching using a chemical etching method. The LIDE method is an example of a method of forming the first and second concave grooves 221 and 232. However, a method of forming the first and second concave grooves 221 and 232 is not necessarily limited thereto.

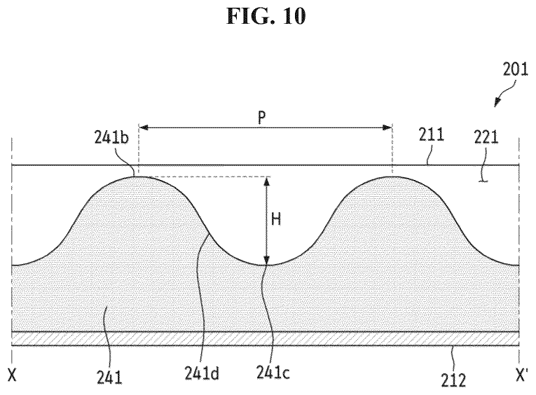

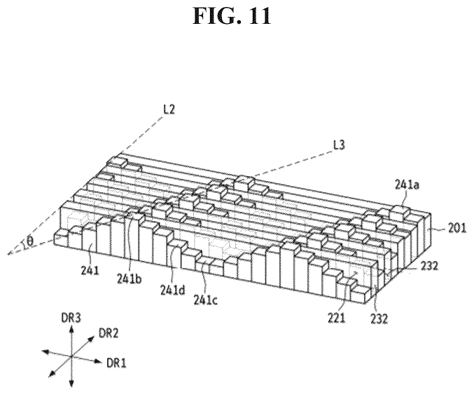

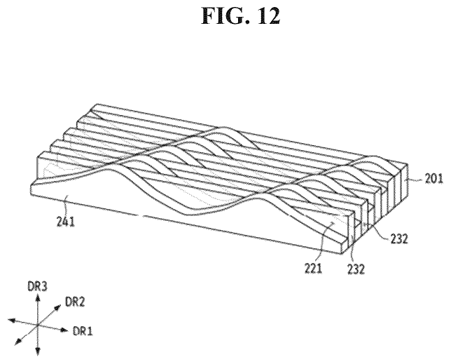

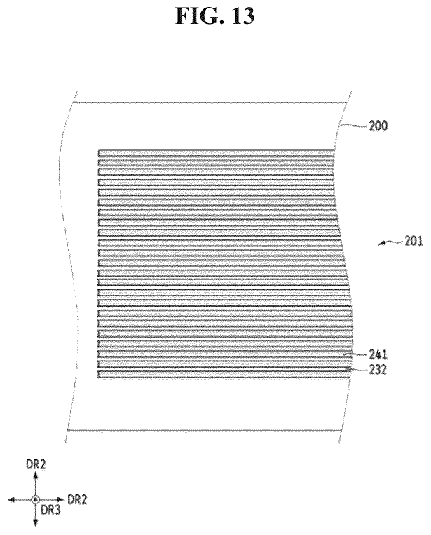

FIG. 9 is an enlarged cross-sectional view illustrating the first and second concave grooves of FIG. 8 and filling resin patterns filled in the first and second concave grooves, FIG. 10 is a side cross-sectional view of a first filling resin pattern taken along line X-X1 in FIG. 9, FIG. 11 is a side perspective view of the first filling resin pattern of FIG. 9 and is a schematic view of the first filling resin pattern, FIG. 12 is a side perspective view of the first filling resin pattern of FIG. 9, and FIG. 13 is a plan view of the first and second concave grooves and first and second filling resin patterns of FIG. 9.

Referring to FIG. 9, filling resin patterns 241 and 242 may be positioned inside the first and second concave grooves 221 and 232, respectively, by filling (e.g., disposing in) each of the first and second concave grooves 221 and 232 with a filling resin.

In an embodiment, the filling resin patterns 241 and 242 may include a plurality of first filling resin patterns 241 continuously disposed inside the plurality of first concave grooves 221 and a plurality of second filling resin patterns 242 having a reverse shape to the first filling resin pattern 241 based on the first line L1 and continuously disposed inside the plurality of second concave grooves 232.

In an embodiment, the plurality of first filling resin patterns 241 and second filling resin patterns 242 may be alternately disposed one by one so as not to overlap each other (e.g., in a plan view). However, arrangement and disposition states of the plurality of first and second filling resin patterns 241 and 242 are not necessarily limited thereto.

In an embodiment, the first and second filling resin patterns 241 and 242 may be formed by filling (e.g., disposing in) the first and second concave grooves 221 and 232 with filling resins having substantially the same refractive index as the window 200 in which the concave grooves 221 and 232 are formed, to prevent refraction of light according to the shapes of the first and second concave grooves 221 and 232, such as to prevent a moiré phenomenon due to the refraction of the light. For example, to prevent the moiré phenomenon, such as to prevent the refraction of the light according to a shape of the pattern portion 201, the first and second filling resin patterns 241 and 242 may be formed by filling (e.g., disposing in) the inside of the pattern portion 201 with a filling resin manufactured to have a refractive index similar to that of glass.

The first and second filling resin patterns 241 and 242 may have substantially the same refractive index as the window 200, and refractive indices of the filling resin and the window 200 will be compared with each other and described. For example, in an embodiment the filling resin has the same refractive index as the glass within a visible light range so that light modulation effects such as refraction and reflection are minimized at an interface with a transparent panel. Unless materials are completely the same as each other, it may not be easy for the materials to have the exact same refractive index within the entire wavelength range of visible light. For example, even though a material of the filling resin is selected to have the same refractive index as the transparent panel for light of some wavelength bands, the material of the filling resin may have a different refractive index from the transparent panel for light of the other wavelength bands. For example, the filling resin may have the same refractive index as the transparent panel for light of a first wavelength band belonging to a wavelength band of the visible light, and may have a different refractive index from the transparent panel for light of a second wavelength band belonging to the wavelength band of the visible light. Here, the different refractive index may refer to a difference in refractive index greater than or equal to about 0.01. In an embodiment, a wavelength range in which the glass and the filling resin have the same refractive index within a wavelength range of the visible light according to such a standard may be less than or equal to about 50% of the entire wavelength range of the visible light. However, embodiments of the present disclosure are not necessarily limited thereto.

In an embodiment, the first and second filling resin patterns 241 and 242 may include one or more filling resins selected from a urethane-based resin, an epoxy-based resin, a polyester-based resin, a polyether-based resin, an acrylate-based resin, an acrylonitrile-butadiene-styrene (ABS) resin, and rubber. However, embodiments of the present disclosure are not necessarily limited thereto. For example, the first and second filling resin patterns 241 and 242 may include one or more filling resins selected from phenylene, polyimide, polyamide, polycarbonate, polyethylene naphthalate, and polyethyleneterephthalate. However, embodiments of the present disclosure are not necessarily limited thereto.

In the first and second filling resin patterns 241 and 242 formed using such filling resins, the filling resins each filled in the first concave groove 221 and the second concave groove 232 may be the same filling resin or different filling resins from each other. Types of the filling resins and combinations of materials of the filling resins of the first and second concave grooves 232 may be various, but are not necessarily limited thereto.

The plurality of first filling resin patterns 241 may be positioned inside the first concave grooves 221 positioned in the window upper surface 211, and first resin surfaces 241a of the first filling resin patterns 241 may be exposed through the openings of the first concave grooves 221. The plurality of first filling resin patterns 241 may be disposed to be spaced apart from each other along the horizontal direction, which is the surface direction of the window upper surface 211.

The plurality of first filling resin patterns 241 may be arranged to correspond to the number of first concave grooves 221. For example, in an embodiment in which the number of first concave grooves 221 is odd for the purpose of the symmetry of the folded state when the window 200 is folded, the number of first filling resin patterns 241 may also be odd and may be greater than the number of second filling resin patterns 242. However, embodiments of the present disclosure are not necessarily limited thereto.

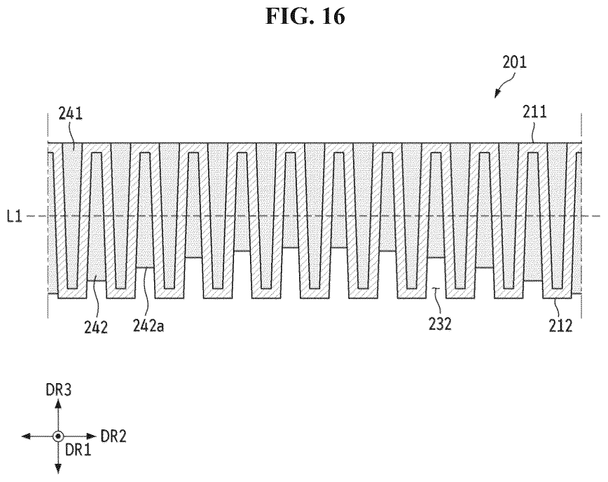

The plurality of second filling resin patterns 242 may be positioned inside the second concave grooves 232 positioned in the window lower surface 212, and in an embodiment in which the filling resins are completely filled inside the second concave grooves 232 as illustrated in FIG. 9, a height of the second filling resin patterns 242 and a height of the second concaves groove 232 may be the same as each other as illustrated in FIG. 9. Alternatively, in an embodiment in which the second filling resin patterns 242 are only partially filled inside the second concave grooves 232, first resin surfaces 242a of the second filling resin patterns 242 may be exposed through the openings of the second concave grooves 232, for example, as illustrated in FIG. 16. The plurality of second filling resin patterns 242 may be disposed to be spaced apart from each other along the horizontal direction, which is the surface direction of the window lower surface 212.

In an embodiment, the plurality of second filling resin patterns 242 may be arranged to correspond to the number of second concave grooves 232, and accordingly, the number of second filling resin patterns 242 may be less than the number of first filling patterns 241. However, embodiments of the present disclosure are not necessarily limited thereto.

As described above, each first filling resin pattern 241 may be positioned so that the first resin surface 241a is exposed to the window upper surface 211 and may have a cross-sectional shape of a protrusion portion protruding towards the window lower surface 212 based on a cross section of FIG. 9, and each second filling resin pattern 242 may be positioned to be exposed to the window lower surface 212 and may have a cross-sectional shape of a protrusion portion protruding towards the window upper surface 211 based on the cross section of FIG. 9.

In an embodiment, each first filling resin pattern 241 may have a semicircular cross-sectional shape or a polygonal cross-sectional shape such as a trapezoidal shape. However, each first filling resin pattern 241 is not necessarily limited thereto, and may be formed in various shapes.

In an embodiment, each second filling resin pattern 242 may have the same shape as the first filling resin pattern 241 and have a semicircular cross-sectional shape or a polygonal cross-sectional shape such as a trapezoidal shape, but may be disposed in a reverse cross-sectional shape to the first filling resin pattern 241 based on the first line L1. However, a shape of the second filling resin pattern 242 is not necessarily limited to the semicircular cross-sectional shape or the polygonal cross-sectional shape such as the trapezoidal shape, and may also be various polygonal cross-sectional shapes. In addition, in some embodiments the second filling resin patterns 242 may also be disposed alternately with the first filling resin patterns 221 in a different shape from the first filling resin patterns 241.

In the plurality of first and second filling resin patterns 241 and 242 described above, the first filling resin patterns 241 and the second filling resin patterns 242 may be formed in the window upper surface 211 and the window lower surface 212, respectively, using an inkjet printing method.

In an embodiment, the first filling resin patterns 241 may be formed by filling (e.g., disposing in) the first concave grooves 221 with the filling resins using the inkjet printing method, and the second filling resin patterns 242 may be formed by overturning the window 200 and filling (e.g., disposing in) the second concave grooves 232 with the filling resins using the inkjet printing method.

In this embodiment, the first and second filling resin patterns 241 and 242 may be formed by filling the first and second concave grooves 221 and 232 with the filling resins once or multiple times using the inkjet printing method. However, embodiments of the present disclosure are not necessarily limited thereto.

In an embodiment, as a filling method of the filling resins, a method of completing filling by injecting the filling resins into the first concave grooves 221 but injecting the filling resins into the first concave grooves 221 while moving along the first concave grooves 221 once or multiple times may be used. In an embodiment, after a process of forming the first filling resin patterns 241 with the filling resins filled (e.g., disposed) inside the first concave grooves 221 is completed, the second filling resin patterns 242 may be formed by attaching a protective film to the window upper surface 211 so as to cover the first filling resin patterns 241, overturning the window 200 to allow the window lower surface 212 to be positioned upward, and injecting the filling resins while moving the second concave grooves 232, but injecting the filling resins into the second concave grooves 232 while moving along the second concave grooves 232 once or multiple times. A method of forming the first and second filling resin patterns 241 and 242 by filling the first and second concave grooves 221 and 232 with the filling resins is not necessarily limited to the inkjet printing method, and may be variously applied as long as it is a printing method capable of printing patterns with the filling resins.

In an embodiment, the first and second resin patterns 241 and 242 formed by injecting the filling resins into the first and second concave grooves 221 and 232 may be disposed to have different respective heights or be asymmetrical to each other by making the numbers of times the filling resins are injected into the first and second concave grooves 221 and 232 and amounts of the filling resins injected into the first and second concave grooves 221 and 232 different from each other as described above.

For example, referring to FIG. 9, in an embodiment the first filling resin patterns 241 adjacent to each other may form a step therebetween by making amounts of the filling resins injected into the respective first concave grooves 221 different from each other, such as making heights of the plurality of first filling resin patterns 241 different from each other (e.g., have varying heights). The heights of the plurality of first filling resin patterns 241 being different from each other may include at least two of the plurality of first filling resin patterns 241 having different heights from each other. In an embodiment, a connection line connecting the first resin surfaces 241a of the first filling resin patterns 241 to each other may have a curved line shape, that is, a parabola shape directed towards the window lower surface 212. For example, the first resin surfaces 241a may be uppermost surfaces (e.g., in the third direction DR3) of each of the plurality of first filling resin patterns 241.

In an embodiment, the first concave grooves 221 are not completely filled with the filling resins and are only partially filled with the filling resins as described above, and the second concave grooves 232 are completely filled with the filling resins, such that heights of the second concave grooves 232 and heights of the second filling resin patterns 242 may be the same as each other and heights of the second filling resin patterns 242 adjacent to each other may also be the same as each other. In this embodiment, the second filling resin patterns 242 may have the same height, and a connection line connecting the second filling resin patterns 242 adjacent to each other to each other may have a straight line shape as illustrated in FIG. 9. For example, a connection line connecting lowermost surfaces (e.g., in a direction opposite to the third direction DR3) of each of the second filling resin patterns 242 adjacent to each other may have a straight line shape.

In an embodiment in which the first concave grooves 221 are filled with the filling resin so that there are steps and the second concave grooves 232 are equally filled with the filling resins, shapes of the first and second filling resin patterns 241 and 242 may be asymmetrical to each other based on the first line L1, as illustrated in FIG. 9.

Referring to FIGS. 10 and 11, in an embodiment the first filling resin patterns 241 and the second filling resin patterns 242 are alternately arranged and the first filling resin patterns 241 are formed at different heights to have steps defined therebetween, and accordingly, a connection line connecting the first resin surfaces 241a of the plurality of first filling resin patterns 241 adjacent to each other to each other may have a wavy shape including mountain portions 241b, ridge portions 241d, and valley portions 241c. In an embodiment, the connection line may have the wavy shape such as a sine function graph as described above. However, embodiments of the present disclosure are not necessarily limited thereto. For example, the connection line may have a triangular wavy shape or various polygonal wavy shapes such as a quadrangular shape, a pentagonal shape, and a hexagonal shape in some embodiments.

In an embodiment, when the connection line connecting the first filling resin patterns 241 to each other has the wavy shape as illustrated in FIGS. 10 and 11, the connection line connecting the second filling resin patterns 242 adjacent to each other to each other may have the straight line shape as illustrated in FIG. 9. Here, FIG. 11 illustrates the first filling resin pattern 241 in a shape of several bar graphs having steps to show that a height of the first filling resin pattern 241 changes to the mountain portion 241b and the valley portion 241c within one first concave groove 221, such as to represent the first filling resin pattern 241 formed by filling the first concave groove 221 with the filling resin at different heights. For example, FIG. 11 is provided for convenience of explanation and illustration, and when the filling resins are filled, the connection line connecting the first resin surfaces 241a of the first filling resin patterns 241 to each other may be a curved line as illustrated in FIGS. 10 and 11. In addition, in a case of the second filling resin patterns 242, the connection line connecting the second filling resin patterns 242 adjacent to each other to each other has the straight line shape as in FIG. 9, and thus, illustration of the second filling resin patterns 242 has been omitted in FIG. 11 for convenience of explanation. In addition, it has been illustrated in FIGS. 11 and 12 that the first filling resin pattern 241 is higher than the first concave groove 221, but this is for convenience of illustration and explanation, and an actual shape and shape of the first filling resin pattern 241 may be the same as those illustrated in FIGS. 9 and 10.

In the first filling resin pattern 241, a portion having the highest position from a bottom surface of the first concave groove 221 to the first resin surface 241a, which is an upper surface of the first filling resin pattern 241 may be the mountain portion 241b, a portion having the lowest position from the bottom surface of the first concave groove 221 to the first resin surface 241a, which is the upper surface of the first filling resin pattern 241 may be the valley portion 241c, and an inclined line, which is a connection line connecting the mountain portion 241b and the valley portion 241c to each other, may be defined as the ridge portion 241d.

Accordingly, in an embodiment the first filling resin pattern 241 may have a form in which the mountain portions 241b, the ridge portions 241d, and the valley portions 241c are continuously repeated within the first concave groove 221 along the transverse direction DR1 such as along a length direction of the first concave groove 221. However, embodiments of the present disclosure are not necessarily limited thereto.

As an example, referring to FIGS. 11 and 13, in an embodiment one first filling resin pattern 241 having the mountain portion 241b, the valley portion 241c, and the ridge portion 241d may have a different height from another first filling resin pattern 241 with one second filling resin pattern 242 positioned in an adjacent second concave groove 232 interposed therebetween. For example, one first filling resin pattern 241 and another first filling resin pattern 241 may have a height difference therebetween and accordingly, form a step.

In addition, a pitch P between the mountain portions 241b in one first filling resin pattern 241 and a pitch P between the mountain portions 241b in another first filling resin pattern 241 adjacent to the one first filling resin pattern 241 may be the same as or different from each other.

In addition, in an embodiment, when the second filling resin pattern 242 has mountain portions, valley portions, and ridge portions like the first filling resin pattern 241, a pitch P between the mountain portions in the second filling resin pattern 242 and the pitch P between the mountain portions 241b in the first filling resin pattern 241 may be the same as or different from each other.

Referring to FIG. 11, the plurality of first filling resin patterns 241 may be disposed adjacent to each other, and the first filling resin patterns 241 adjacent to each other may be disposed to be tilted by a predetermined inclination angle.

In an embodiment, in the first filling resin patterns 241 adjacent to each other along the longitudinal direction DR2, which is the first direction which may be an extending direction of a first edge of the window 200, an angle θ formed between a straight line L3 connecting to each other the mountain portions 241b of the first filling resin patterns 241 adjacent to each other and a straight line L2 along the longitudinal direction DR2, which is the first direction, may be greater than 0° and less than 90°. In addition, in an embodiment an angle formed between the straight line L3 connecting the mountain portions 241b of the first filling resin patterns 241 to each other and the transverse direction DR1, which is the second direction corresponding to a direction that crosses the longitudinal direction DR2, which is the first direction, and is an extension direction of the first concave groove 221, may be greater than 0° and less than 90°.

For example, in an embodiment the angle θ formed between the straight line L3 connecting the mountain portions 241b of the first filling resin patterns 241 adjacent to each other to each other and the straight line L2 along the longitudinal direction DR2, which is the first direction, may be in a range of about 3° to about 15°, such as about 13°. However, embodiments of the present disclosure are not necessarily limited thereto. In an embodiment in which the angle θ is greater than or equal to about 3°, it is possible to suppress the occurrence of a moiré while providing ease of filling when filling the filling resin, and when the angle is less than or equal to about 15°, such as about 13°, a moiré reduction rate may be excellent. However, embodiments of the present disclosure are not necessarily limited thereto.

In addition, in an embodiment in which the angle θ formed between the straight line L3 connecting the mountain portions 241b of the first filling resin patterns 241 adjacent to each other to each other and the straight line L2 along the longitudinal direction DR2, which is the first direction, is in a range of about 3° to about 15°, the angle formed between the straight line L3 connecting the mountain portions 241b of the first filling resin patterns 241 to each other and the transverse direction DR1, which is the second direction, may be in a range of about 74° to about 86°. However, embodiments of the present disclosure are not necessarily limited thereto.

A moiré phenomenon may be prevented by tilting of the first filling resin patterns 241 as described above. Here, a moiré is an interference pattern created when two or more periodic patterns overlap each other, and the moiré phenomenon may be defined as a phenomenon in which a moiré period increases to be visible with the naked eyes of the user when pixels of the display panel and the pattern portion 201 have similar periodicity.

For example, when the patterns of the pattern portion 201 of the window 200 is formed to have periodicity, the periodicity of the patterns in the window 200 overlaps periodicity of patterns such as the pixels of the display panel 400, such that the moiré phenomenon may occur due to geometric interference.

In an embodiment, the patterns of the pattern portion 201 of the window 200 may be formed in the form of a straight line parallel to a folding direction to secure a folding performance. In this embodiment, the moiré may occur due to interference between the pixels of the display panel and the patterns formed in the window 200.

The periodicities overlap each other as described above, such that the geometric interference may occur, which may be obtained as the moiré phenomenon. The moiré phenomenon is a factor that reduces visibility of the display device, and it is possible to reduce the occurrence of the moiré phenomenon by adjusting a bias angle within a range of about 3° to about 15° based on the reference line described above.

In an embodiment in which the first and second filling resin patterns 241 and 242 have the bias angle in a range of about 3° to about 15° to prevent the moiré phenomenon, specifically to prevent the moiré from occurring due to the overlap between the periodicities, it is possible to reduce the moiré phenomenon due to the overlap between the periodicity of the pixels of the display panel 400 and the periodicity of the patterns of the window 200. In an embodiment in which the bias angle is in a range of about 3° to about 15° as described above, the periodicity of the pixels of the display panel 400 and the periodicity of the patterns of the window 200 deviate from each other, and thus, it is possible to reduce the moiré phenomenon due to the overlap between the periodicities. It is possible to suppress deterioration of screen quality caused by the moiré phenomenon.

Referring to FIG. 12, the first filling resin patterns 241 tilted as described above may have a curved line shape such as a sine graph shape unlike FIG. 11 in which the first filling resin patterns 241 are illustrated in a shape of bar graphs in a schematic view of the first filling resin patterns 241 for convenience of explanation. However, embodiments of the present disclosure are not necessarily limited thereto.

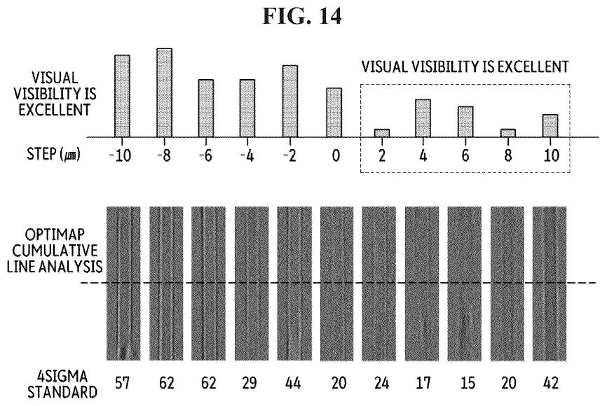

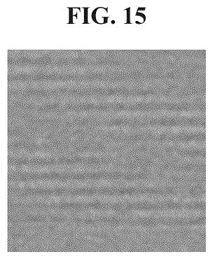

FIG. 14 is a graph illustrating moiré evaluation results according to steps between a mountain portion and a valley portion of FIG. 9, and FIG. 15 is a photograph illustrating a state in which a moiré occurs when a height difference between the mountain portion and the valley portion of FIG. 9 is less than 2.

Referring to FIGS. 14 and 15, a height difference H (see FIG. 10) between the mountain portion 241b and the valley portion 241c in the first filling resin pattern 241 may be, for example, in a range of about 2 to about 15 μm, such as about 2 to about 10 μm, or about 10 μm. For example, the height difference H may be in the range of about 5 to about 15 μm. However, embodiments of the present disclosure are not necessarily limited thereto. Here, samples for each step were produced in units of 2 μm, visual recognition evaluation was performed, and an Optimap image was created and illustrated in FIG. 14. Referring to FIG. 14, when the height difference is less than 2 μm, a moiré prevention effect may not almost occur. When the height difference exceeds the range described above, it may be confirmed that a moiré phenomenon is aggravated and a moiré pattern is viewed. For example, an error range of the height difference H between the mountain portion 241b and the valley portion 241c may be less than about 10 μm. As an example, the error range of the height difference H between the mountain portion 241b and the valley portion 241c may be about 3 μm. In addition, the error range of the height difference H between the mountain portion 241b and the valley portion 241c may be set in consideration of an error when the first filling resin pattern 241 is filled. For example, when the error range of the height difference H between the mountain portion 241b and the valley portion 241c is 1.5 times or more, 2 times or more, or 5 times or more, a height difference may be less than the height difference between the mountain portion 241b and the valley portion 241c of the first filling resin pattern 241. However, embodiments of the present disclosure are not necessarily limited thereto. Referring to visibility test results by the height difference H between the mountain portion 241b and the valley portion 241c in the first filling resin pattern 241, when the height difference H between the mountain portion 241b and the valley portion 241c is less than 2 μm, for example, −10 μm, −8 μm, −6 μm, −4 μm, or −2 μm or does not exist, it may be confirmed that a moiré pattern that is visible to the eyes is directly viewed as illustrated in FIG. 15. To the contrary, when the height difference H (see FIG. 10) between the mountain portion 241b and the valley portion 241c in the first filling resin pattern 241 is, for example, in a range of about 2 to about 10 μm, it may be confirmed through FIG. 14 that a moiré is reduced.

FIGS. 16 to 20 are enlarged cross-sectional views illustrating pattern portions according to embodiments of the present disclosure.

Referring to FIG. 16, in an embodiment a line connecting mountain portions and valley portions of the second filling resin patterns 241 to each other is a curved line instead of a straight line, which is different from an embodiment of FIG. 9 in which the line connecting adjacent mountain portions 241b of the first filling resin patterns 241 to each other is a curved line. For example, a connection line connecting lowermost surfaces (e.g., in a direction opposite to the third direction DR3) of each of the second filling resin patterns 242 adjacent to each other may be a curved line.

In an embodiment, in the first filling resin patterns 241, the filling resins may be completely filled from bottom surfaces of the first concave grooves 221 to a surface of the window upper surface 211, and in the second filling resin patterns 242, the filling resins may be filled to be stepped so as to form an arc based on a cross section.

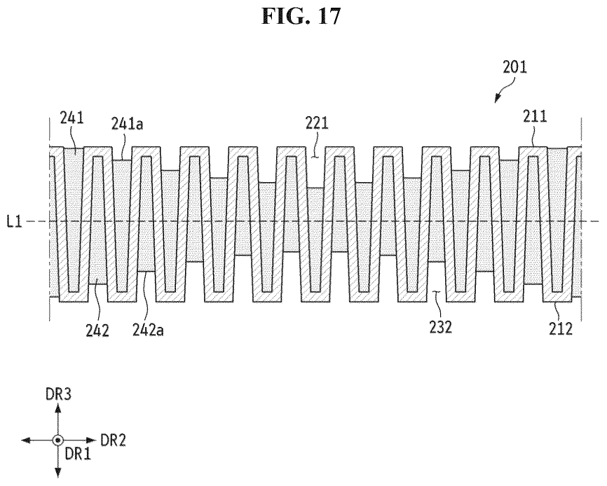

Referring to FIG. 17, in an embodiment both the first and second filling resin patterns 241 and 242 may include mountain portions 241b and valley portions 241c, which is different from FIG. 9 in which only the first filling resin pattern includes the mountain portions 241b and the valley portions 241c and FIG. 16 in which only the second filling resin pattern includes the mountain portions 241b and the valley portions 241c.

In an embodiment, a line connecting adjacent mountain portions 241b of the first filling resin patterns 241 to each other may be a curved line, and a line connecting adjacent mountain portions 241a of the second filling resin patterns 242 to each other may be a curved line oppositely symmetrical to the curved line of the first filling resin patterns 241 based on the first line L1. In this embodiment, the first and second filling resin patterns 241 and 242 are formed at a relatively small thickness at a position corresponding to the folding area FDA, and accordingly, the pattern portion 201 may reduce bending stress during folding.

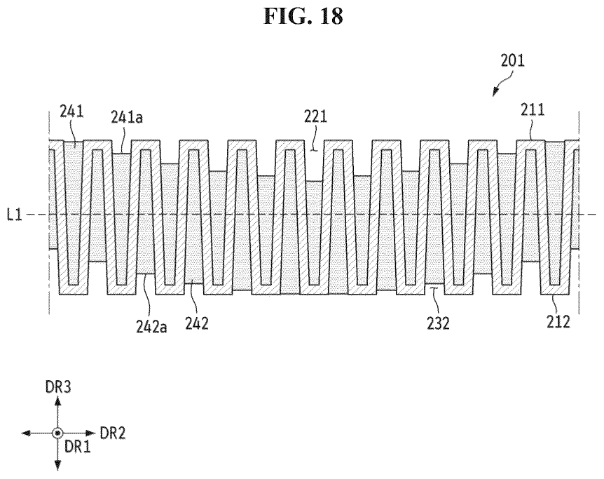

Referring to FIG. 18, in an embodiment a pair of curved lines are disposed symmetrical to each other in the same direction based on the first line L1, which is different from FIG. 17 in which a pair of curved lines are disposed oppositely symmetrical to each other. In this embodiment, the sums of thicknesses of the first filling resin patterns 241 and the second filling resin patterns 242 filled in the same first concave grooves 221 and second concave grooves 232 may be continuously the same as each other, such that mechanical stability may be increased.

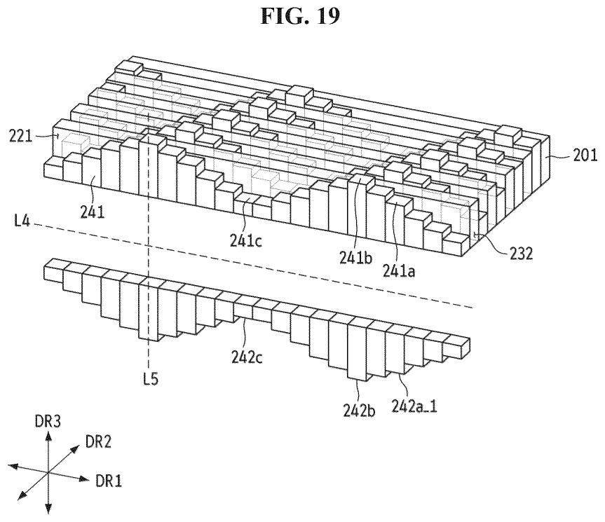

Referring to FIG. 19, in an embodiment in which the pitch P of the first filling resin pattern 241 and the pitch P of the second filling resin pattern 242 are the same as each other, such as when the first filling resin pattern 241 and the second filling resin pattern 242 are symmetrical to each other based on a transverse reference line L4, the mountain portion 241b of the first filling resin pattern 241 and the mountain portion 241b of the second filling resin pattern 242 may coincide with a longitudinal reference line L5 (e.g., extending in the third direction DR3). When the mountain portion 241b and the mountain portion 241b coincide with each other, consistency of pattern arrangement may be provided, such that the moiré reduction effect may be further increased.

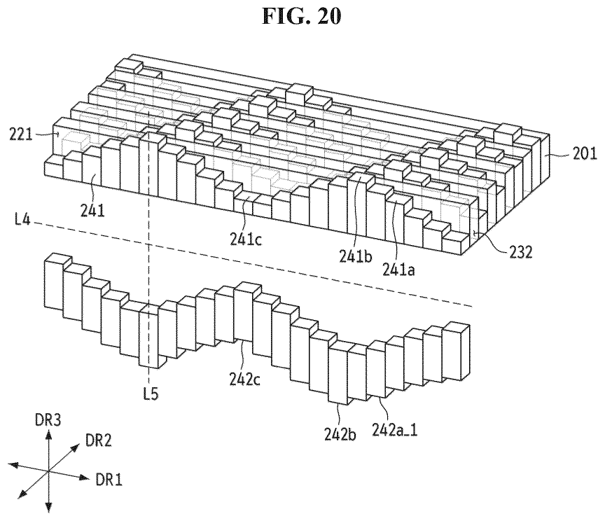

Referring to FIG. 20, when the pitch P of the first filling resin pattern 241 and the pitch P of the second filling resin pattern 242 are the same as each other, such as when the first filling resin pattern 241 and the second filling resin pattern 242 are symmetrical to each other based on a transverse reference line L4, the mountain portion 241b of the first filling resin pattern 241 and the valley portion 241c of the second filling resin pattern 241 may coincide with a longitudinal reference line L5. When the mountain portion 241b and the valley portion 241c coincide with each other, their thicknesses may be compensated for by each other, such that mechanical strength may be increased to the window 200 and distortion may be prevented during folding to support the window 200 so that symmetrical folding is possible.

In a case of the display device 10, a moiré phenomenon may occur, and such a moiré phenomenon may be a factor that reduces visibility of the display device 10. However, the first and second filling resin patterns 241 and 242 have the bias angle in a range of about 3° to about 15°, and accordingly, it is possible to effectively reduce the moiré phenomenon that occurs due to the overlap between the periodicities and prevent the deterioration of the screen quality.

In concluding the detailed description, those skilled in the art will appreciate that many variations and modifications can be made to the described embodiments without substantially departing from the principles of the present disclosure. Therefore, the described embodiments of the present disclosure are used in a generic and descriptive sense only and not for purposes of limitation.

What is claimed is:

1. A display device comprising:
a display panel including a folding area; and
a window disposed on the display panel,
wherein the window includes a pattern portion disposed at a position overlapping the folding area, the window including a first edge extending in a first direction,
the pattern portion includes a plurality of groove patterns and a plurality of filling resin patterns disposed in the plurality of groove patterns,
the plurality of filling resin patterns is arranged to be spaced apart from each other along the first direction,
the plurality of groove patterns extends in a second direction crossing the first direction, and
each of the plurality of filling resin patterns has varying heights along the second direction, wherein mountain portions and valley portions are alternately arranged along the second direction.

2. The display device of claim 1, wherein an angle between a line connecting adjacent mountain portions of adjacent filling resin patterns of the plurality of filling resin patterns that are adjacent to each other along the first direction and the first direction is greater than 0° and less than 90°.

3. The display device of claim 1, wherein an angle between a line connecting adjacent mountain portions of adjacent filling resin patterns of the plurality of filling resin patterns that are adjacent to each other along the first direction and the second direction is greater than 0° and less than 90°, and wherein the first direction and the second direction are perpendicular to each other.

4. The display device of claim 1, wherein a height difference between the mountain portions and the valley portions of each of the plurality of filling resin patterns is in a range of about 5 to about 15 μm.

5. The display device of claim 1, wherein:
the plurality of filling resin patterns includes a first filling resin pattern disposed in a first surface of the window and a second filling resin pattern disposed in a second surface of the window that is a surface opposite to the first surface in a thickness direction of the window and faces the display panel; and
a mountain portion of the first filling resin pattern and a mountain portion of the second filling resin pattern are positioned on a same axis along the thickness direction of the window.

6. The display device of claim 1, wherein:
the plurality of filling resin patterns includes a first filling resin pattern disposed in a first surface of the window and a second filling resin pattern disposed in a second surface of the window that is a surface opposite to the first surface in a thickness direction of the window and faces the display panel; and
a mountain portion of the first filling resin pattern and a valley portion of the second filling resin pattern are positioned on a same axis along the thickness direction of the window.

7. The display device of claim 1, wherein:
the plurality of filling resin patterns includes a first filling resin pattern disposed in a first surface of the window and a second filling resin pattern disposed in a second surface of the window that is a surface opposite to the first surface in a thickness direction of the window and faces the display panel; and
the first filling resin pattern and the second filling resin pattern have shapes symmetrical to each other.

8. The display device of claim 1, wherein:
the plurality of filling resin patterns includes a first filling resin pattern disposed in a first surface of the window and a second filling resin pattern disposed in a second surface of the window that is a surface opposite to the first surface in a thickness direction of the window and faces the display panel; and
the first filling resin pattern and the second filling resin pattern have shapes asymmetrical to each other.

9. The display device of claim 1, wherein:
the plurality of filling resin patterns includes a plurality of first filling resin patterns disposed in a first surface of the window and a plurality of second filling resin patterns disposed in a second surface of the window that is a surface opposite to the first surface in a thickness direction of the window and faces the display panel; and
a pitch between adjacent mountain portions in the plurality of first filling resin patterns and a pitch between adjacent mountain portions in the plurality of second filling resin patterns are equal to each other.

10. The display device of claim 1, wherein mountain portions of adjacent filling resin patterns of the plurality of filling resin patterns that are adjacent to each other along the first direction have different heights from each other and form a step therebetween.

11. The display device of claim 1, wherein a connection line connecting the mountain portions and the valley portions of each of the plurality of filling resin patterns to each other along the second direction has a wavy shape.

12. The display device of claim 1, wherein:
the plurality of filling resin patterns includes a first filling resin pattern disposed in a first surface of the window and a second filling resin pattern disposed in a second surface of the window that is a surface opposite to the first surface in a thickness direction of the window and faces the display panel; and
the first filling resin pattern has a shape that protrudes from a surface of the first surface towards the second surface,
the second filling resin pattern has a shape that protrudes from a surface of the second surface towards the first surface, and
the first filling resin pattern and the second filling resin pattern are alternately arranged along the first direction.

13. The display device of claim 1, wherein the plurality of filling resin patterns includes one or more filling resins selected from a urethane-based resin, an epoxy-based resin, a polyester-based resin, a polyether-based resin, an acrylate-based resin, an acrylonitrile-butadiene-styrene (ABS) resin, and rubber.

14. The display device of claim 1, wherein:
the plurality of groove patterns includes a plurality of first concave grooves defined in a first surface of the window and a plurality of second concave grooves defined in a second surface of the window that is a surface opposite to the first surface and faces the display panel; and
the plurality of first concave grooves and the plurality of second concave grooves are alternately arranged.

15. A transparent panel for a display device, comprising:
a transparent panel including a pattern portion including a plurality of groove patterns recessed in a thickness direction from one surface, a first non-pattern portion positioned on a first side of the pattern portion in a first direction and having one surface that is flat, and a second non-pattern portion positioned on an opposite second side of the pattern portion in the first direction and having one surface that is flat; and
a plurality of filling resin patterns at least partially filled in the plurality of groove patterns of the pattern portion,
wherein the plurality of filling resin patterns is arranged to be spaced apart from each other along the first direction,
the plurality of groove patterns extends in a second direction crossing the first direction,
each of the plurality of filling resin patterns has varying heights along the second direction, wherein mountain portions and valley portions are alternately arranged along the second direction, and
an angle between a line connecting adjacent mountain portions of adjacent filling resin patterns of the plurality of filling resin patterns that are adjacent to each other along the first direction and the first direction is greater than 0° and less than 90°.

16. The transparent panel for a display device of claim 15, wherein an angle between the line connecting the adjacent mountain portions of the adjacent filling resin patterns and the second direction is greater than 0° and less than 90°, and wherein the first direction and the second direction are perpendicular each other.

17. The transparent panel for a display device of claim 15, wherein a height difference between the mountain portions and the valley portions of each of the plurality of filling resin pattern is in a range of about 5 to about 15 μm.

18. An electronic device comprising:
a display panel including a folding area; and
a window disposed on the display panel and including an upper surface and a lower surface,
wherein the window includes a pattern portion disposed at a position overlapping the folding area;
the pattern portion includes a plurality of first concave grooves recessed towards the lower surface of the window and a plurality of second concave grooves recessed towards the upper surface of the window, the plurality of first concave grooves and the plurality of second concave grooves are alternately arranged along a first direction, wherein each of the plurality of first concave grooves and the plurality of second concave grooves extends in a second direction crossing the first direction,
a plurality of first filling resin patterns is disposed in the plurality of first concave grooves and a plurality of second filling resin patterns is disposed in the plurality of second concave grooves, and
at least one of the plurality of first filling resin patterns and the plurality of second filling resin patterns has varying heights along the second direction, and includes mountain portions and valley portions alternately arranged along the second direction.

19. An electronic device of claim 18, wherein an angle between a line connecting adjacent mountain portions of adjacent filling resin patterns of the at least one of the plurality of first filling resin patterns and the plurality of second filling resin patterns and the first direction is in a range of about 3° to about 15°.

20. An electronic device of claim 18, wherein:
a line connecting adjacent first filling resin patterns of the plurality of first filling resin patterns that are adjacent along the first direction has a curved line shape; and
a line connecting adjacent second filling resin patterns of the plurality of second filling resin patterns that are adjacent along the first direction has a straight line shape.
